(19) United States
(12) Patent Application Publication
(10) Pub. No.: US 2010/0182857 A1
(43) Pub. Date: Jul. 22, 2010

(54) TESTER FOR SEMICONDUCTOR DEVICE AND SEMICONDUCTOR DEVICE

(75) Inventors: Tetsuya ARAI, Tokyo (JP); Toshio TSUCHIDA, Fukuoka-shi (JP)

Correspondence Address: YOUNG & THOMPSON, 209 Madison Street, Suite 500, Alexandria, VA, 22314, US

(73) Assignee: ELPIDA MEMORY, INC., Tokyo (JP)

(21) Appl. No.: 12/689,696

(22) Filed: Jan. 19, 2010

(30) Foreign Application Priority Data
Jan. 21, 2009 (JP) 2009-011172

(51) Int. Cl. G11C 7/00; G11C 29/00; G11C 8/18

(52) U.S. Cl. 365/193; 365/201; 365/194; 365/233.11; 365/189.09

(57) ABSTRACT

An apparatus testing a semiconductor device may include, but is not limited to, a first strobe signal generating circuit and a detecting circuit. The first strobe signal generating circuit generates a first strobe signal in response to a reference clock supplied from the semiconductor device. The detecting circuit detects a data signal, supplied from the semiconductor device, based on the first strobe signal.

### BACKGROUND OF THE INVENTION

1. Field of the Invention

The present invention relates to a tester for testing a semiconductor device, and a semiconductor device to be tested by the tester.

Priority is claimed on Japanese Patent Application No. 2009-11172, filed Jan. 21, 2009, the content of which is incorporated herein by reference.

2. Description of the Related Art

Some examples of semiconductor devices typically DRAMs (Dynamic Random Access Memories) may include, but is not limited to, a memory that performs reception and transmission of data input and output signals DQ by using the timing of data strobe signals DQS.

FIG. 9 shows a state at the time of readout of this type of semiconductor device. FIG. 9 shows that if a read command RED as a command signal CMD synchronized with an external clock signal CLK is given to the semiconductor device, the data strobe signal DQS and the data input and output signal DQ are output from the semiconductor device at CL (CAS Latency)=2, or at the second clock from the read command RED. Then both of the signals are transitioned in synchronization with rising and falling of the external clock signal CLK.

In FIG. 9, D1 to D8 represent logic levels of the data input and output signal DQ which is output from one input and output terminal of one semiconductor device, and data 1 and data 0 output alternately by eight bits. Similarly, for the data strobe signal DQS, data 1 and data 0 output alternately by eight bits.

In the real usage state of the semiconductor device, data D1 to D8 are received and transmitted in synchronization with the rising and falling of the data strobe signal DQS.

In the tester for testing the above-mentioned semiconductor device, the times (tAC and tDQSCK, respectively, in FIG. 9) from, for example, the second clock of the external clock signal CLK to change points of the data input and output signal DQ and the data strobe signal DQS are measured, and it is determined for quality whether it is within a predetermined range.

Quality determination is performed by outputting a strobe signal STB within the tester, reading out, at the time of generation thereof, whether the data input and output signal DQ and the data strobe signal DQS exist at an expected voltage or higher or lower by a comparator within pin electronics, and determine whether to match with the expected value in a logic comparator within a test signal control section.

However, since the strobe generation time is preset in a user program to be input to the tester, the following problem occurs.

For example, in FIG. 9, there is supposed a case where a semiconductor device (referred to as sample 2) separate from the above-mentioned semiconductor device (referred to as sample 1) outputs a data input and output signal DQ2 and a data strobe signal DQS2 from one input and output terminal.

Then, when the generation time of the strobe signal STB is set up as in FIG. 9, with respect to sample 1, it is determined to be of good quality if the expected values of the logic comparator are set to 1, 0, 1, 0, 1, 0, 1, 0 like the data D1 to D8.

On the other hand, since the data output time is deviated with respect to the time of the strobe signal STB even though sample 2 outputs the same data as those of the sample 1, it is determined to be of poor quality.

However, considering the real usage state of sample 2, it is not necessarily the case that sample 2 is of poor quality even though it is determined to be of poor quality by the tester.

As described above, in a real usage state, the data strobe signal DQS (shown in FIG. 9 as the data input and output signal DQ2 and the data strobe signal DQS2, respectively, for the sample 2) is used for reception and transmission of the data input and output signal DQ.

Consequently, when tDQSCK (which is time difference between tAC and tDQSCK, and is set to tDQSQ and tDQSQ2 in FIG. 9) is within a predetermined time for either of the samples 1 and 2, either of them is determined to be of good quality.

Therefore, when quality determination of each sample is performed, it is preferable to previously measure tDQSCK and tDQSCK2 with respect to each sample in consideration of its real usage state, to determine the generation time of the tester strobe signal based on this, and to perform quality determination by whether data equivalent to the expected values are output.

For example, Japanese Unexamined Patent Application, First Publication, No. 2001-201532 addresses the following semiconductor device evaluating apparatus. That is, the timing of the rising or falling of the data strobe signal DQS is read out by a plurality of signal readout circuits that performs a sampling operation with a strobe pulse composed of multiphase pulses gradually provided with a phase difference. The timing of the rising or falling of the data strobe signal DQS is regulated by the phase numbers of the multiphase pulses in which the change point of the data strobe signal DQS is detected. Then, the phase numbers are stored in a memory provided within the tester. Thus, in testing the device, the readout of the data input and output signal DQ from the device at a timing obviously determined by the phase numbers is performed. It is determined whether the change point is present at the timing, and quality determination of the device is performed depending on the determination result.

### SUMMARY

In one embodiment, an apparatus testing a semiconductor device, the apparatus may include, but is not limited to, a first strobe signal generating circuit that generates a first strobe signal in response to a reference clock supplied from the semiconductor device; and a detecting circuit that detects a data signal, supplied from the semiconductor device, based on the first strobe signal.

In another embodiment, a method of testing a semiconductor device may include, but is not limited to, supplying a reference clock and a data signal from the semiconductor device to an apparatus; generating a first strobe signal in response to the reference clock; and detecting the data signal based on the first strobe signal.

In still another embodiment, an apparatus may include, but is not limited to, a first pin receiving a reference clock signal; a second pin receiving a data signal; a first strobe signal generating circuit electrically coupled to the first pin and generating a first strobe signal in response to the reference clock signal; a second strobe signal generating circuit generating a second clock signal, the second clock signal being free from the reference clock signal; a selector receiving the first and second strobe signal and outputting one of the first and second strobe signal; a reference voltage generating circuit generating a reference voltage; and a detection circuit electrically coupled to the second pin to receive the data signal, receiving the one of the first and second strobe signal and the reference voltage, and comparing a first logic level of the data signal with a second logic level of the reference voltage at a timing based on the one of the first and second strobe signal.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a diagram illustrating the configuration of a tester for testing a semiconductor device in accordance with a first preferred embodiment of the present invention;

FIG. 2 is a diagram illustrating the general configuration of a tester to illustrate the background of the tester of FIG. 1;

FIG. 3 is a timing chart illustrating signal waveforms for a semiconductor device to be tested by the tester of FIG. 1;

FIG. 4 is a diagram illustrating the configuration of a tester for testing a semiconductor device in accordance with a first modified embodiment of the present invention;

FIG. 5 is a diagram illustrating the configuration of a semiconductor device to be tested by a tester free of a delay line in accordance with a second modified embodiment of the present invention;

FIG. 6 is a diagram illustrating the configurations of an output buffer control circuit and an output buffer circuit which are included in the semiconductor device of FIG. 5;

FIG. 7 is a timing chart illustrating signal waveforms for the semiconductor device of FIG. 5;

FIG. 8 is a diagram illustrating the configuration of a tester for testing the semiconductor device of FIG. 5; and

FIG. 9 is a timing chart illustrating signal waveforms for a semiconductor device to be tested by a tester in accordance with the related art.

### DETAILED DESCRIPTION OF THE PREFERRED EMBODIMENTS

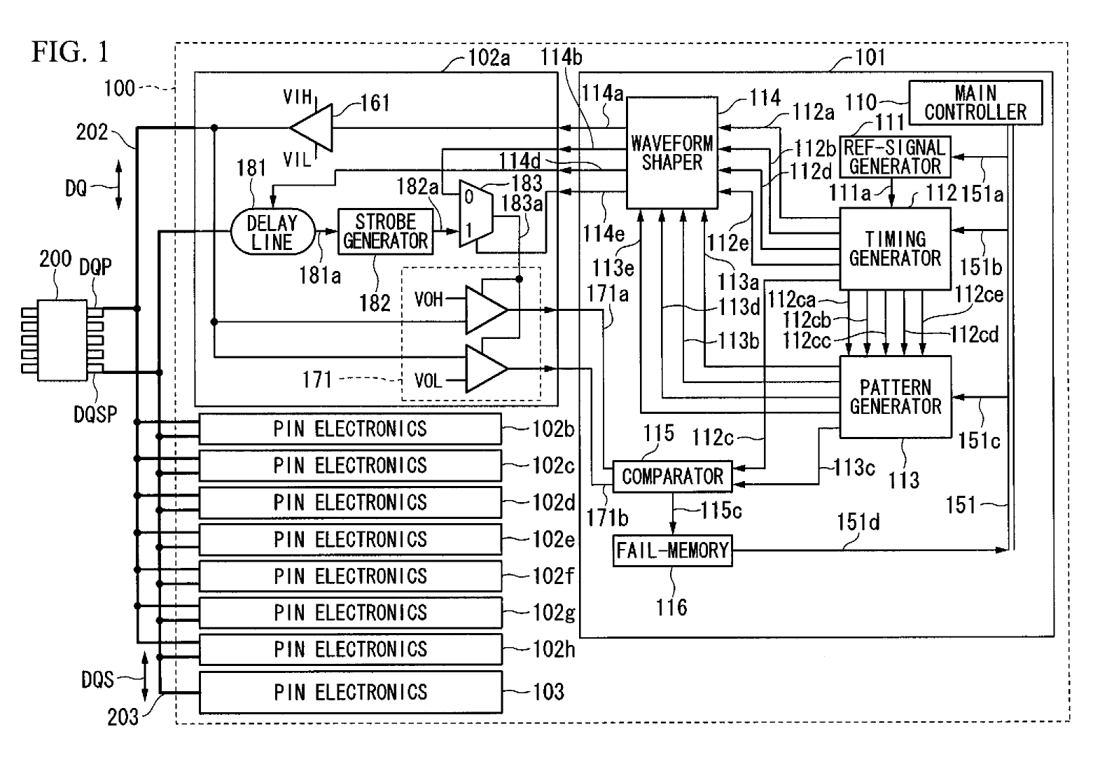

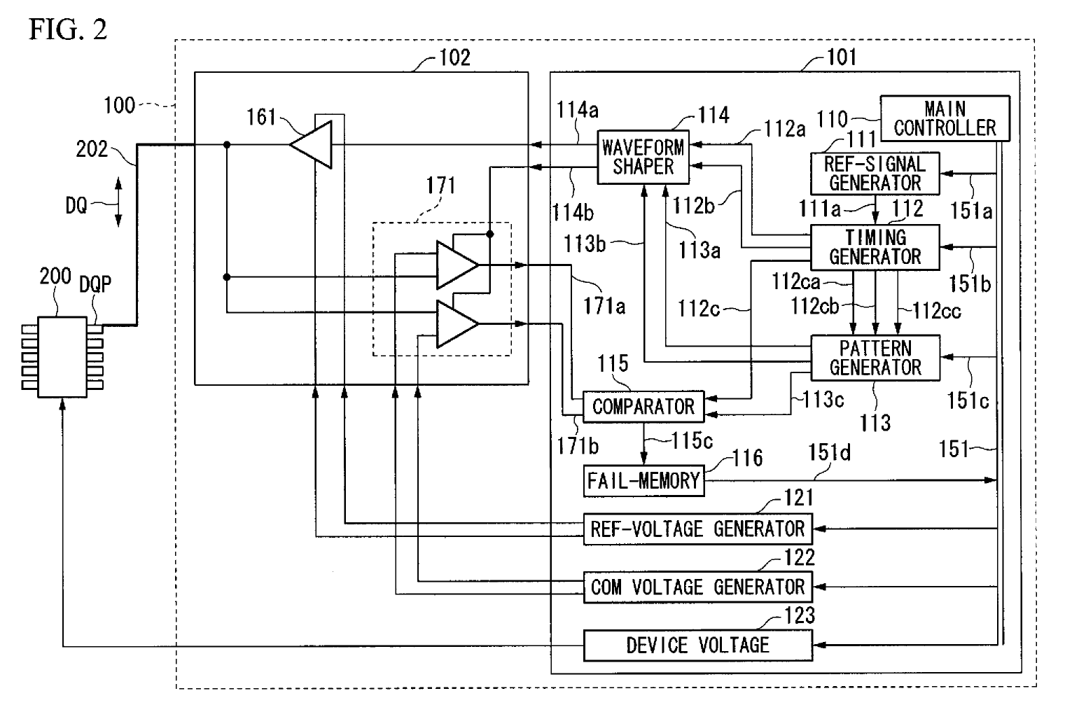

Before describing the present invention, the related art will be explained in detail with reference to FIG. 2, in order to facilitate the understanding of the present invention. The outline of a general tester will be described with reference to FIG. 2, prior to the description of the tester shown in FIG. 1.

FIG. 2 shows the general configuration of the tester. A tester 100 may include a test signal control section 101 and a pin electronics 102, in which a device subject to the test 200 is tested.

The test signal control section 101 may include, but is not limited to, a main controller 110, a reference signal generator 111, a timing generator 112, a pattern generator 113, a waveform shaper 114, a logic comparator 115, a fail memory 116, a reference voltage source 121, a comparative voltage source 122, a device power source 123 and the like.

The main controller 110 may include, but is not limited to, a computer system, and transmits a tester control signal via a tester bus 151 to control the reference signal generator 111 and the like in accordance with a program for testing a device to be tested prepared by a user.

The reference signal generator 111 receives a tester control signal 151a from the tester bus 151, and generates a reference signal 111a which becomes a time reference of a test waveform applied to the device to be tested.

The timing generator 112 is configured so that a tester control signal 151b and the reference signal 111a are input from the tester bus 151 thereto, and counts the reference signal 111a in accordance with the tester control signal 151b to generate a phase signal 112a and the like for a driver having a desired cycle and time delay.

Generally, a signal for a test cycle (test rate), strobe, or control is exemplified as the phase signal.

In FIG. 2, the phase signal 112a of a driver, a phase signal 112b of a strobe, and a phase signal 112e for a logic comparator are shown as the phase signal.

In addition, phase signals 112ca, 112cb, and 112cc to be output to the pattern generator 113 are also shown.

The pattern generator 113 is configured so that a tester control signal 151c is input from the tester bus 151 thereto and the phase signal is given from the timing generator 112 thereto, and generates pattern data signals for testing the device to be tested.

As the pattern generator 113, for example, when the device to be tested is a memory device typically a DRAM, ALPG (Algorithmic Pattern Generator) configured to be capable of generating any test patterns is exemplified.

In FIG. 2, as the pattern data signal, shown are a pattern data signal 113a for the driver generated at the timing of the phase signal 112ca by receiving the tester control signal 151c, a pattern data signal 113b for the strobe generated at the timing of the phase signal 112cb by receiving the tester control signal 151c, and a pattern data signal 113c for the logic comparator generated at the timing of the phase signal 112cc by receiving the tester control signal 151c.

The waveform shaper 114 is configured to receive the pattern data signal from the pattern generator 113, and to output a real waveform on the basis of the phase signal from the timing generator 112.

In FIG. 2, the waveform shaper 114 performs logic synthesis on the pattern data signal 113a for the driver at the timing of the phase signal 112a for the driver, and generates a driver driving signal 114a for driving a driver 161 within the pin electronics 102.

In addition, the waveform shaper 114 performs logic synthesis on the pattern data signal 113b for the strobe at the timing of the phase signal 112b for the strobe, and generates a strobe signal 114b to be input to a comparator 171 within the pin electronics 102.

The logic comparator 115 compares logic levels of signals (comparative result signal 171a and comparative result signal 171b) from the comparator 171 within the pin electronics 102 described later with an expected value (pattern data signal 113c for the logic comparator) to be input from the pattern generator 113 at the timing of the signal (phase signal 112c for the logic comparator) to be input from the timing generator, and outputs a quality determining signal 115a.

In addition, the fail memory 116 is configured so that the above-mentioned quality determining signal 115a is input thereto, and the quality determination result is stored therein. The fail memory 116 transmits a determination signal 151d to the main controller 110 via the tester bus 151 after the end of testing of the device 200.

The reference voltage source 121 is configured to supply a predetermined DC voltage to the driver 161 within the pin electronics 102. That is, the reference voltage source supplies high/low DC voltage levels (VIH and VIL) which become output amplitudes of the waveforms applied to the device 200.

The comparative voltage source 122 is configured to supply a predetermined DC voltage to the comparator 171 within the pin electronics 102. That is, the comparative voltage source supplies reference voltages for comparison (VOH and VOL) which become threshold level voltages for converting an analog output signal from the device 200 into a logic signal.

The device power source 123 is a variable power source that supplies a DC voltage to the device 200.

The pin electronics 102 and the device 200 will be described.

The pin electronics 102 is connected to the device 200 via a transmission line 202.

Although as the device 200, a DRAM is exemplified, the device, in particular, is limited to the DRAM, and may be a SRAM (Static Random Access Memory) or a system LSI (Large Scale Integration).

FIG. 2 shows a state where a data input and output terminal DQP of the device 200 is connected to the pin electronics 102 via the transmission line 202.

Although not shown in FIG. 2, terminals other than the data input and output terminal DQP in the device 200 are also connected to other pin electronics provided than those equivalent to the pin electronics 102 via each of the transmission lines.

In addition, the pin electronics is connected to each of the test signal control sections equivalent to the above-mentioned test signal control section 101, and the device 200 is tested in the tester 100.

When the device 200 is in the writing operation, the driver 161 in the pin electronics 102 applies the voltage VIH or VIL to the data input and output terminal DQP via the transmission line 202. Data 0 or 1 are input to the device 200.

When the device 200 is in the readout operation, the comparator 171 in the pin electronics 102 receives input of the voltage level equivalent to data 0 or 1. The comparator 171 compares such a voltage level with the voltage VOL or VOH, and outputs the comparative result signals 171a and 171b with respect to the above-mentioned logic comparator 115.

Meanwhile, the above-mentioned comparison is performed by the voltage level of the input signal at a point of time where the strobe signal 114b is applied.

In the tester described above, the reading time for reading the data input output signal DQ from the semiconductor device is different from the times which define the rising or falling edges of the data strobe signal DQS. This time difference will make it difficult to countermeasure the problem with jitter, for example, variations of the data input output signal DQ due to time passage or thermal variations.

A large number of different test patterns can be used to countermeasure the above problem. If there is evaluated a large number of test items using a large number of different test patterns, it is necessary to define the timing of the data strobe signal DQS for each test time. This method will be time-consuming.

The invention will be now described herein with reference to illustrative embodiments. Those skilled in the art will recognize that many alternative embodiments can be accomplished using the teaching of the present invention and that the invention is not limited to the embodiments illustrated for explanatory purpose.

In accordance with an embodiment, a tester may include, but is not limited to, a receiving circuit that receives data and a reference clock from the semiconductor device; a first strobe signal generating circuit that generates a first strobe signal synchronized with the reference clock; and a detecting circuit that detects the data using the first strobe signal. The reference clock is used for transmitting data between the semiconductor device and the tester.

The tester detects data that have been output from the semiconductor device. The detection is made using the strobe pulse that is generated in synchronization with the rising and/or falling edges of the reference clock. The reading time for reading the data from the semiconductor device has almost no time difference from the time that defines the rising and/or falling edges of the reference clock. Such almost no time difference will make it unnecessary to consider jitter, for example, the variations of the data due to time passage or thermal variation. The reference clock is given to the tester by the semiconductor device which also gives the data to the tester. The data and the reference clock are commonly subject to thermal variations.

The tester allows the test in test conditions corresponding to the actual use conditions of the semiconductor device. The relationship between the data and the reference clock is the same between the test mode and the actual use.

There is no need to define the timings of the reference clock for every test items as long as the tester of the embodiment is used. Thus, there is no increase in the necessary time for test due to the process for defining the timings of the reference clock. Use of the above test will allow the tester to test the semiconductor device at a shortened time.

In one embodiment, an apparatus testing a semiconductor device, the apparatus may include, but is not limited to, a first strobe signal generating circuit that generates a first strobe signal in response to a reference clock supplied from the semiconductor device; and a detecting circuit that detects a data signal, supplied from the semiconductor device, based on the first strobe signal.

In some cases, the reference clock may be supplied from the semiconductor device to be accompanied with the data signal. In some cases, the reference clock may be a data strobe signal generated by the semiconductor device.

In some cases, the apparatus may further include, but is not limited to, a delay circuit that receives the reference clock from the semiconductor device. The delay circuit delays the reference clock to generate a delayed reference clock. The first strobe signal generating circuit may receive the delayed reference clock from the delay circuit, the first strobe signal generating circuit generates the strobe signal in response to the delayed reference clock.

In some cases, the apparatus may further include, but is not limited to, a delay control signal generating circuit that generates a delay control signal. The delay control signal generating circuit supplies the delay control signal to the delay circuit. The delay circuit delays the reference clock based on the delay control signal.

In some cases, the apparatus may further include, but is not limited to, a second strobe signal generating circuit that generates a second strobe signal at a predetermined timing; and a selector that selects one of the first and second strobe signals. The detecting circuit may receive a selected one of the first and second strobe signals from the selector. The detecting circuit detects the data signal using the selected one of the first and second strobe signals.

In some cases, the apparatus may further include, but is not limited to, a selector control signal generating circuit that generates a selector control signal. The selector control signal generating circuit supplies the selector control signal to the selector. The selector selects one of the first and second strobe signals based on the selector control signal.

In some cases, the apparatus may further include, but is not limited to, a plurality of pin electronics connected to the semiconductor device. Each of the plurality of pin electronics receives the data signal and the reference clock. Each of the plurality of pin electronics may include the first strobe signal generating circuit and the detecting circuit.

In some cases, the apparatus may further include, but is not limited to, a plurality of pin electronics connected to the semiconductor device. Each of the plurality of pin electronics receives the data signal and the reference clock. Each of the plurality of pin electronics may include, but is not limited to, the first strobe signal generating circuit, the detecting circuit and the delay circuit.

In some cases, the apparatus may further include, but is not limited to, a plurality of pin electronics connected to the semiconductor device, and a test signal control unit connected to the plurality of pin electronics. Each of the plurality of pin electronics receives the data signal and the reference clock. Each of the plurality of pin electronics may include the first strobe signal generating circuit, and the detecting circuit. The test signal control unit may include the delay circuit.

In some cases, the apparatus may include a plurality of pin electronics connected to the semiconductor device, and a test signal control unit connected to the plurality of pin electronics. Each of the plurality of pin electronics receives the data signal and the reference clock. Each of the plurality of pin electronics may include the first strobe signal generating circuit, the detecting circuit and the selector. The test signal control unit may include the second strobe signal generating circuit.

In some cases, the semiconductor device may include, but is not limited to, a data output unit that outputs the data signal; and a delayed reference clock output unit that outputs a delayed reference clock. The data signal is output based on the delayed reference clock. The semiconductor device supplies the data signal to the apparatus and supplies the delayed reference clock to the apparatus as the reference clock.

In another embodiment, a method of testing a semiconductor device may include, but is not limited to, supplying a reference clock and a data signal from the semiconductor device to an apparatus; generating a first strobe signal in response to the reference clock; and detecting the data signal based on the first strobe signal.

The method may further include, but is not limited to, delaying the reference clock to generate a delayed reference clock. Generating the strobe signal may include generating the strobe signal in response to the delayed reference clock.

The method may further include, but is not limited to, generating a second strobe signal at a predetermined timing; and selecting one of the first and second strobe signals. Detecting the data signal may include detecting the data signal using the selected one of the first and second strobe signals.

In some cases, generating the first strobe signal and detecting the data signal may be performed by each of a plurality of pin electronics included in an apparatus testing the semiconductor device.

In some cases, delaying the reference clock may be performed in an apparatus testing the semiconductor device.

In some cases, delaying the reference clock may be performed in the semiconductor device.

In still another embodiment, an apparatus may include, but is not limited to, a first pin receiving a reference clock signal; a second pin receiving a data signal; a first strobe signal generating circuit electrically coupled to the first pin and generating a first strobe signal in response to the reference clock signal; a second strobe signal generating circuit generating a second clock signal, the second clock signal being free from the reference clock signal; a selector receiving the first and second strobe signal and outputting one of the first and second strobe signal; a reference voltage generating circuit generating a reference voltage; and a detection circuit electrically coupled to the second pin to receive the data signal, receiving the one of the first and second strobe signal and the reference voltage, and comparing a first logic level of the data signal with a second logic level of the reference voltage at a timing based on the one of the first and second strobe signal.

In some cases, the apparatus may further include, but is not limited to, a delay circuit connected between the first pin and the first strobe signal generating circuit so as to delay the reference clock signal supplied from the first pin. The delay circuit generates a delayed reference clock signal. The first strobe signal generating circuit generates the first strobe signal in response to the delayed reference clock signal.

The general configuration of the tester has been shown as described above, and now the description will be again continued with FIG. 1. In the meantime, for purposes of avoiding repetition of the above-mentioned description, the same numbers are attached to the parts equivalent to each of the parts of FIG. 2, and the differences with FIG. 1 will be obviously described.

First of all, in the test signal control section 101 of the embodiment, a delay control signal 114d and a selector control signal 114e are newly added as the output signals of the waveform shaper 114.

Both of the signals are signals for controlling a pin electronics 102a described later, and for the purpose of generating both of the signals, the output signals are newly added even in the timing generator 112 and the pattern generator 113 respectively.

That is, in the timing generator 112, added are phase signals 112d, 112e, 112cd, and 112ce generated by being input with the tester control signal 151b from the tester bus 151 and being input with the reference signal 111a from the reference signal generator 111.

Further, in the pattern generator 113, added are a pattern data signal 113d for delay control generated at the timing of the phase signal 112cd by receiving the tester control signal 151c, and a pattern data signal 113e for selector control generated at the timing of the phase signal 112ce by receiving the tester control signal 151c, respectively.

In the waveform shaper 114, the delay control signal 114d is generated by performing logic synthesis on the pattern data signal 113d for delay control at the timing of the phase signal 112d for delay control. In addition, the selector control signal 114e is generated by performing logic synthesis on the pattern data signal 113e for selector control at the timing of the phase signal 112e for selector control.

Further, in FIG. 1, the pin electronics 102a is different from the pin electronics 102 in FIG. 2 in the following respect.

The pin electronics 102a in FIG. 1 includes a delay line 181, a strobe generating circuit 182, and selector 183.

In the delay line 181, a transmission line 203 is connected to an input stage thereof, the amount of delay is controlled by the delay control signal 114d to be input from the test signal control section 101, and a delay signal 181a is output from an output stage thereof.

Meanwhile, the delay line 181 is capable of being configured to be delayed by the number of gate stages, configured to be delayed by a time constant through a resistive element and a capacitive element and the like, or configured to latch an input signal by an out-of-phase signal, but the delay line may take any configuration among them.

The strobe generating circuit 182 is a circuit that receives the input of the delay signal 181a to output a strobe signal 182a.

The selector 183 is a circuit that selects any of the strobe signal 182a or the strobe signal 114b to be input from the test signal control section 101 in accordance with the logic level of the selector control signal 114e to be input from the test signal control section 101, and outputs a strobe signal 183a.

In particular, the selector 183 outputs the strobe signal 114b when the logic level of the selector control signal 114e is 0, and the strobe signal 182a when the logic level is 1, as the strobe signal 183a.

Other pin electronics 102b to 102h are the same configurations as that of the pin electronics 102a, and are each connected to the device 200 via the transmission line 203.

In addition, although only one device 200 is shown, in the so-called parallel measurement of measuring a plural number simultaneously, the number of the pin electronics is prepared in the tester depending on the number of the devices under test, and a plurality of devices under test is tested.

In FIG. 1, the device 200 is, for example, a DRAM, and includes a data input and output terminal DQP and the data strobe terminal DQSP.

The data input and output terminal DQP is a terminal for inputting and outputting data to and from the memory cell within the DRAM. In FIG. 1, the data input and output terminal DQP and the transmission line 202 are shown by one terminal and one transmission line with other eight terminals and eight transmission lines omitted.

That is, the DRAM (device 200) has the data input and output terminals DQ0P to 7P, and is connected to eight pin electronics 102a to 102h via each of the transmission lines 202, which causes the data input and output signals DQ0 to 7 to be input and output.

Meanwhile, the pin electronics 102b to 102h, of which the internal constituents are omitted in FIG. 1, have the same configuration as that of the pin electronics 102a, and input and output the data input and output signals DQ1 to 7.

In addition, the data strobe terminal DQSP is a terminal for inputting and outputting the data strobe signal DQS used in reception and transmission of data to be input and output to and from the above-mentioned data input and output terminal DQP.

The data strobe terminal DQSP is connected to a pin electronics 103 via the transmission line 203.

The pin electronics 103, of which the internal constituents are omitted in FIG. 1, also has the same configuration as that of the pin electronics 102 in FIG. 2 described above, and inputs and outputs the data strobe signal DQS.

That is, when the device 200 is in a readout operation, the comparator in the pin electronics 103 receives the input of the data strobe signal DQS.

The comparator compares a voltage level of the data strobe signal DQS with the voltage VOL or VOH, and outputs the comparative result with respect to the logic comparator corresponding to the pin electronics 103.

Meanwhile, the above-mentioned comparison is performed by the voltage level of the input signal at a point of time where the strobe signal to be output from the waveform shaper corresponding to the pin electronics 103 is applied.

With such a configuration, it is possible to perform the next test by using the tester 100.

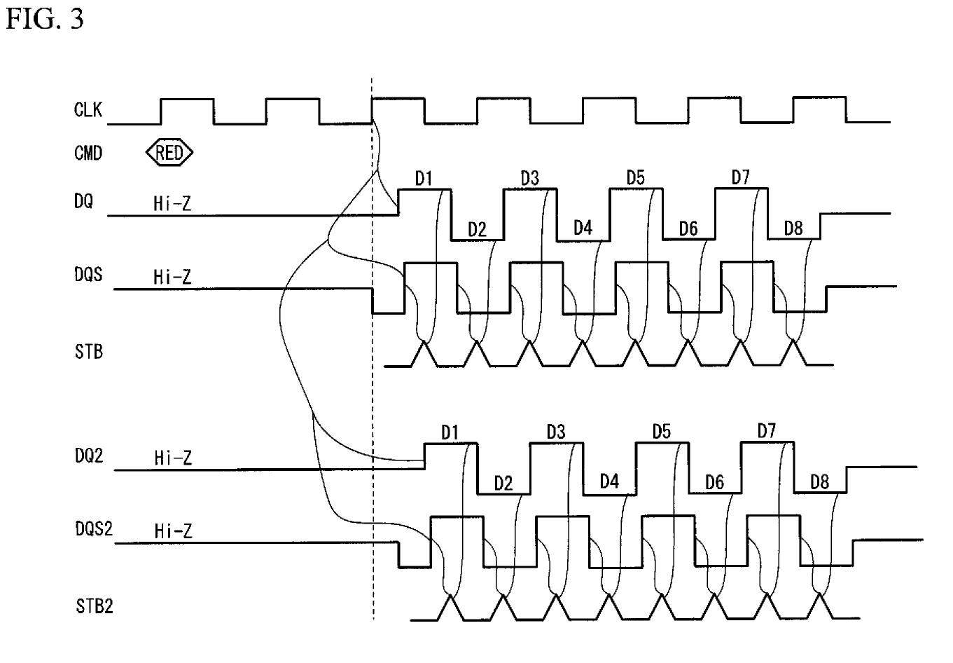

FIG. 3 is a timing chart illustrating a state at the time of readout of the device 200, and the description thereof is continued below with reference to the drawing.

First, in a program for testing the device prepared by a user, the above-mentioned selector control signal 114e will be described with the logic level being set to 1.

In such a case, the strobe signal 183a becomes the strobe signal 182a output by the strobe generating circuit 182 within the pin electronics 102a through the selector 183 within the pin electronics 102a.

Therefore, the comparator 171 reads out the voltage level of the data input and output signal DQ in response to the strobe signal 182a.

FIG. 3 shows a state where two samples of sample 1 and sample 2 are prepared as the device 200, a reading command RED is given to a command signal CMD synchronized with an external clock signal CLK, and 8-bit data are output to each sample from one data input and output terminal at the timing of CL (CAS Latency)=2.

Although the device 200 has been described to include eight input and output terminals in the above description, the description is performed with respect to the data input and output terminal DQ0P for convenience.

In FIG. 3, the data strobe signal DQS, the data input and output signal DQ, and the strobe signal STB are signal waveforms when the test is performed with respect to the sample 1, and the data strobe signal DQS2, the data input and output signal DQ2, and the strobe signal STB2 are signal waveforms when the test is performed with respect to the sample 2.

Further, in FIG. 3, D1 to D8 represent the logic levels of the data input and output signal DQ and DQ2 output from each of the data input and output terminals DQ0P of the sample 1 and the sample 2, and each have an assumption that data 1, 0, 1, 0, 1, 0, 1, 0 like expected values are output.

In addition, since the data strobe signals DQS and DQS2 each are signals to be output from the device 200 used in reception and transmission of the data input and output signals DQ and DQ2, the data strobe signals output, for example, data 1, 0, 1, 0, 1, 0, 1, 0 at almost the same time as the data input and output signals.

As described above, the strobe signal STB for testing the sample 1 is the strobe signal 183a in FIG. 1.

Since the strobe signal 183a is the strobe signal 182a by the selector 183, the strobe signal STB (strobe signal 183a) is generated at the time delayed more by the amount of delay of the delay line 181 than the rising and falling time of the data strobe signal DQS to be output from the sample 1.

Then, the comparator 171 compares the voltage level of the data input and output signal DQ at this time with preset VOH and VOL, and outputs the comparative result signals 171a and 171b.

After that, the logic comparator 115 reads out a signal like the expected value with respect to the sample 1, and generates the quality determining signal 115a as quality determination.

Similarly with respect to the sample 2, variation in the data input and output signal DQ2 is read out by the strobe signal STB2 (strobe signal 183a) generated at the time delayed more by the amount of delay of the delay line 181 than the rising and falling time of the data strobe signal DQS2, whereby quality determination is performed.

In the above description, the logic level of the selector control signal 114e is set to 1.

The logic level is set up in a program for testing the device which is originally prepared by a user.

In addition, the generation time of the strobe signal 114b in FIG. 1 is also set up by such a program.

Therefore, when the logic level of the selector control signal 114e is 0, the strobe signal 183a in FIG. 1 becomes the strobe signal 114b output by the waveform shaper 114.

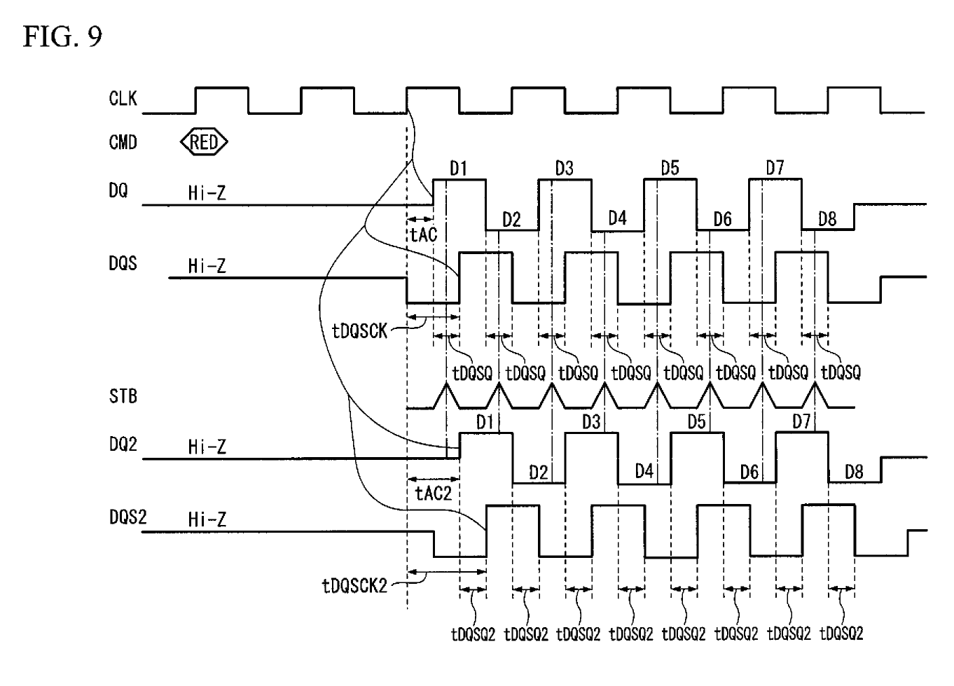

In such a case, in related art, the generation time of the strobe signal is not able to be set up by the sample as described with reference to FIG. 9, and the generation time of the strobe signal is set up collectively with respect to the whole sample.

That is, as described with FIG. 9, it may happen as the case may be that some samples, which should have been originally determined to be of good quality, are determined to be of poor quality by the setup strobe signal by the generation time of the strobe signal, which is due to the consideration that there is the data strobe signal DQS in the reception and transmission of the data input and output signal DQ in the real usage state.

Therefore, when the device 200 is tested by the tester 100 of the embodiment, it is optimal to evaluate as follows by dividing the logic levels of the selector control signal 114e into 0 or 1.

When the logic level of the selector control signal 114e is 0, the strobe signal is generated after the elapse of a predetermined time (for example after the elapse of tAC) from for example the second clock of for example the external clock signal CLK, and values in which the voltage levels of the data input and output signal DQ exist at VOH or higher or VOL or lower are compared by the comparator 171. In addition, values in which the voltage levels of the data strobe signal DQS exist at VOH or higher or VOL or lower after the elapse of for example tDQSC are compared by the comparator 171.

That is, when the logic level of the selector control signal 114e is 0, it is evaluated whether the electrical characteristics tAC and tDQSC of the device 200 are within a predetermined time.

On the other hand, when the logic level of the selector control signal 114e is 1, the amount of delay of the delay line 181 within a semiconductor device 300 is set up so that the strobe signal is generated after the elapse of a predetermined time (for example, after the elapse of tDQSCK) from a change point of the data strobe signal DQS, and values in which the voltage levels of the data input and output signal DQ exist at VOH or higher or VOL or lower are compared by the comparator 171.

Meanwhile, with the delay control signal 114d in FIG. 1 described above, it is possible to perform the evaluation with a good accuracy by setting the amount of delay of the delay line 181 within the semiconductor device 300 to an arbitrary value in a program for testing the device prepared by a user.

In this manner, the tester of the embodiment is a testing apparatus (tester 100) for testing a device (device 200), and is a tester (tester 100) characterized in that a reference clock (data strobe signal DQS) provided for reception and transmission of data along with data (data input and output signal DQ) to be output is output from the device (device 200), and that detection of the data (data input and output signal DQ) is performed in response to a strobe pulse (strobe signal 182a) generated in synchronization with the timing of the rising and falling of the reference clock (data strobe signal DQS).

Herewith, when the voltage level of the data input and output signal DQ to be output from the device (device 200) is read out by the comparator 171 within the pin electronics 102a, since the readout is performed by the strobe signal (strobe signal 182a) for delaying the reference clock (data strobe signal DQS), there is little time difference between the time for regulating the timing of the rising or falling of the reference clock (data strobe signal DQS), and the time for reading out the data (data input and output signal DQ) read out from the device.

For this reason, it is not necessary to consider variations in the data (data input and output signal DQ) varied with the lapse of time (thermal variation), or so-called jitters.

That is, since the above-mentioned reference clock (data strobe signal DQS) is output from the data (data input and output signal DQ) and the device, it is subject to the same thermal variation.

Therefore, according to this embodiment of the invention, an effect is exhibited that it is possible to provide a tester capable of performing a test corresponding to the real usage of the device, that is, a test corresponding to the relationship between the data (data input and output signal DQ) and the reference clock (data strobe signal DQS) to be output along with the data (data input and output signal DQ).

In addition, since there is no increase in test time by regulating the timing of the reference clock for each test item, an effect is also exhibited that it is possible to perform detection of a change of data in a short period of time.

In addition, since each of the comparators in a pin electronics is able to detect data in response to the data strobe signal DQS to be output from the device, an effect is also exhibited that it is possible to deal with variation for each device.

In addition, when the tester is able to simultaneously measure a plurality of devices under test, that is, when it is able to correspond to parallel measurement, since there is no case where the tester performs detection on data collectively, an effect is also exhibited that it is possible to deal with variation for each device.

Meanwhile, in the above description, although there has been described a case where the delay line exists for each pin electronics 102a to 102h, it is also possible to take out the delay line outside the pin electronics.

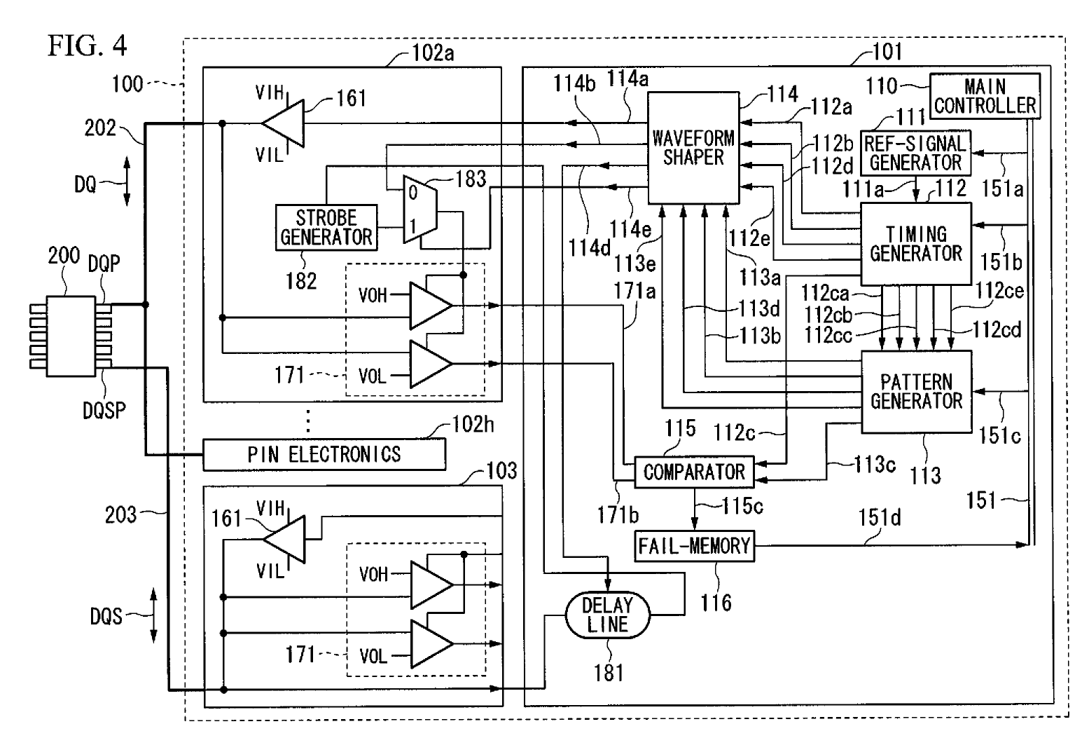

FIG. 4 is a configuration diagram of the tester in such a case.

In FIG. 4, the delay line 181 is provided within the test signal control section 101.

In addition, an input stage of the delay line 181 is connected to the transmission line 203, through which the data strobe signal DQS is transmitted, via the pin electronics 103.

Meanwhile, the tester corresponding to the above-described parallel measurement is provided with the delay lines 181 as much as the number of the devices under test.

When the tester is configured in this manner, an effect is exhibited that it is possible to reduce the number of the delay lines while maintaining the above-described effect.

In addition, a delay line mounting space in the test signal control section can be widened as much as the reduction in a delay line mounting space in the pin electronics, and an effect is also exhibited that it is possible to perform the detection of the data input and output signal with a high degree of accuracy by providing the higher-accuracy delay line.

A semiconductor device according to the embodiment of the invention will be described.

When the delay line is not able to be provided in the inside of the tester as described above, it is possible to provide the delay line within the device.

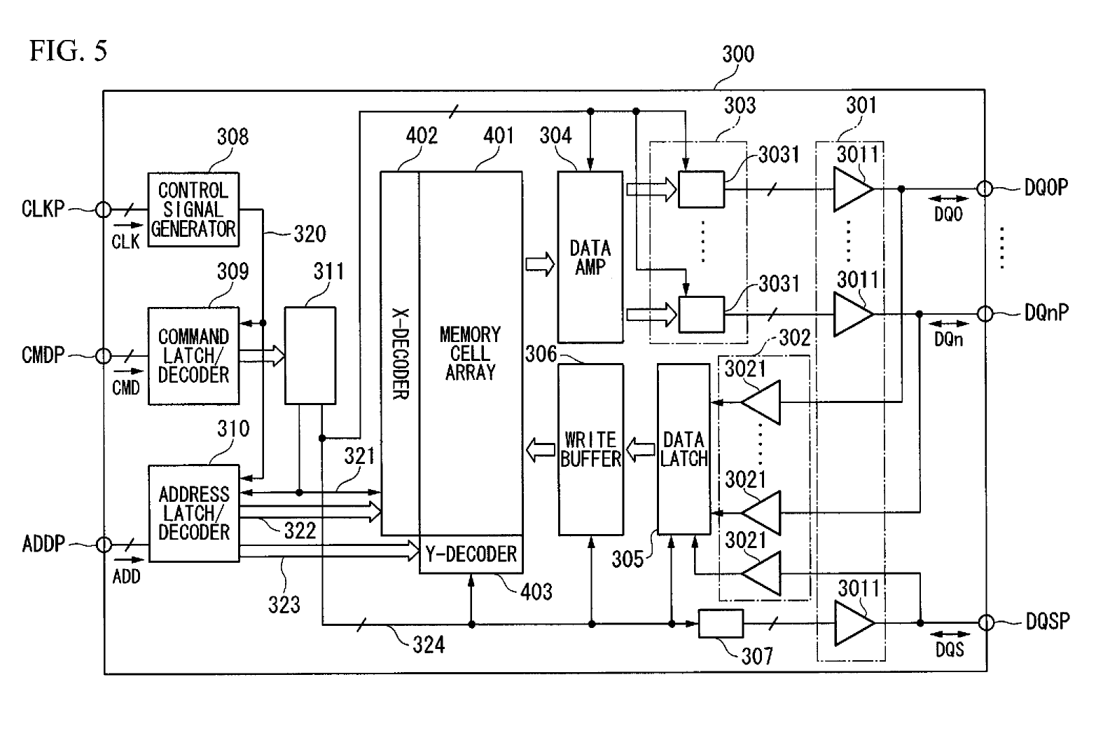

FIG. 5 shows a schematic configuration diagram of the semiconductor device 300 used as such a device.

The semiconductor device 300 includes a CLK input terminal CLKP to which an external clock signal CLK is input, a command input terminal CMDP to which a command signal CMD is input, and an address input terminal ADDP to which an external address signal is input.

In addition, the semiconductor device includes data input and output terminals DQ0P to DQnP to and from which data input and output signals DQ0 to DQn are input and output and a data strobe terminal DQSP to and from which a data strobe signal DQS is input and output.

The semiconductor device 300 includes, as internal circuits, a memory cell array 401 composed of a plurality of memory cells, a X decoder 402 and a Y decoder 403 for selecting a predetermined memory cell within the memory cell array 401, an input circuit 302 composed of a plurality of input buffer circuits 3021, an output buffer control section 303 composed of a plurality of output buffer control circuits 3031, a data amplifier circuit 304, a data latch circuit 305, a write buffer circuit 306, an output buffer control circuit 307 for a data strobe signal, a control signal generating circuit 308, a command input latch and decode circuit 309, an address input latch and decode circuit 310, a control logic circuit 311 and the like.

In addition, an output circuit section 301 includes a plurality of output buffer circuits 3011.

Meanwhile, the details of readout operations the output buffer control circuit 3031, the output buffer control circuit 307 for a data strobe signal, and the output buffer circuit 3011, which are associated with the readout operation, will be described.

First, the basic operation of the semiconductor device 300 according to the this embodiment of the invention will be described.

An internal clock signal 320 generated by the control signal generating circuit 308 is generated on the basis of the external clock signal CLK to be input from the CLK input terminal CLKP.

The command signal CMD and the external address signal ADD are incorporated in the command input latch and decode circuit 309 and the address input latch and decode circuit 310 in response to the internal clock signal 320.

The command signal CMD is decoded by the command input latch and decode circuit 309, and then is input to the control logic circuit 311.

The control logic circuit 311 generates an X address-based control signal 321, a Y address-based control signal 324 and the like in response to an input command, and controls the address input latch and decode circuit 310 for outputting an X address signal 322 and a Y address signal 323, the X decoder 402 and the Y decoder 403, the above-mentioned output circuit section 301 and the like, to perform a desired operation.

In order to write data or to read out data to and from the semiconductor device 300, it is necessary, prior to this, to input an active command (ACT) to the command input terminal CMDP as a command input signal, and to set the memory cell array 401 to be in an active state.

In addition, simultaneously with the active command input, the X address signal is also input to the address input terminal ADDP, and a word line corresponding to the X address within the memory cell array 401 is selected, to thereby cause a cell on the word line to be in a selected state.

In a writing operation, successively, if a write command (WRT) is input to the command input terminal CMDP, and the Y address signal is input to the address input terminal ADDP, writing of data to a cell of the Y address on the above-mentioned word line is performed on the basis of the data input and output signals DQ0 to DQn input from the data input and output terminal DQ0P to DQnP.

That is, the data input and output signals DQ0 to DQn, which are write data, are input to the input circuit 302, and are incorporated in the data latch circuit 305 from the write command (WRT), by rising and falling edge of the data strobe signal DQS input in synchronization with, for example, the one-clock delayed external clock signal CLK, and then are written to the above-mentioned selected memory cell within the memory cell array 401 by the write buffer circuit 306.

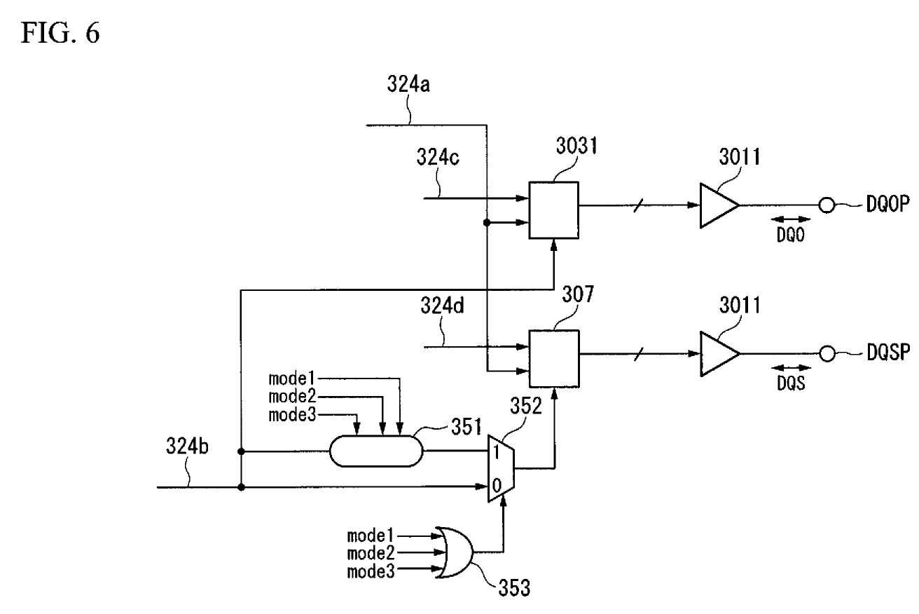

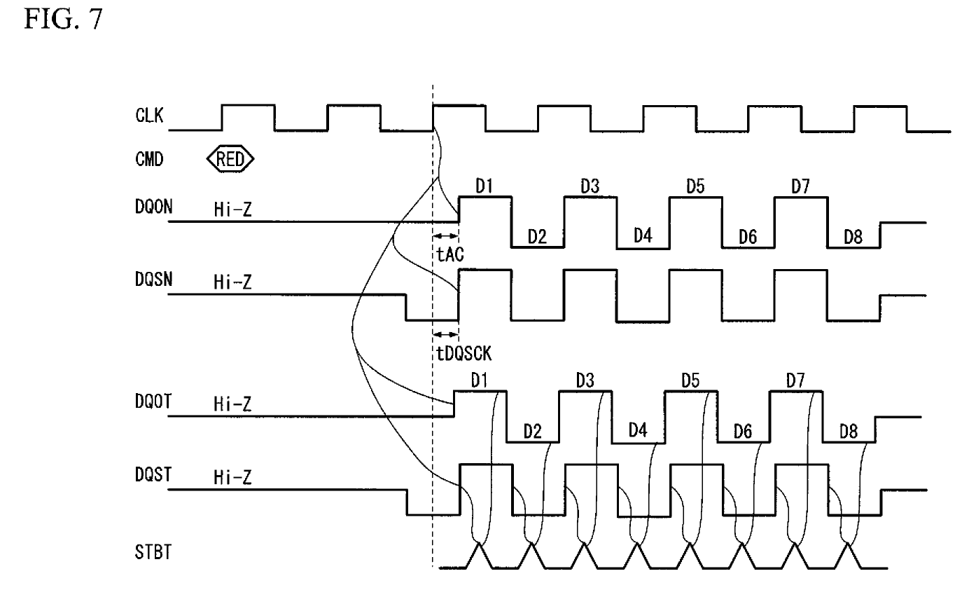

The readout operation will be described with reference to FIG. 6 and FIG. 7.

FIG. 6 is a supplemental explanatory diagram of FIG. 5 illustrating the configurations of the output buffer control circuit and the output buffer circuit in FIG. 5 in more detail.

FIG. 7 is a timing chart illustrating a state at the time of readout of the semiconductor device 300, and shows changes of the data input and output signal and the data strobe signal to be output to the data input and output terminal DQ0P and the data strobe terminal DQSP, divided into a typical operation mode and a test operation mode.

A data input and output signal DQ0N and a data strobe signal DQSN are changes of signals in the typical operation mode, and a data input and output signal DQ0T and a data strobe signal DQST are changes of signals in the test operation mode.

In addition, a strobe signal STBT is a strobe signal generated within the tester at the time of test of the semiconductor device 300 described later.

In FIG. 6, the circuit corresponding to the data input and output terminal DQ0P, out of the above-mentioned output buffer control circuit 3031 and the output buffer circuit 3011, is shown along with the output control signal to be input.

In addition, the output buffer control circuit 307 for a data strobe signal and the output buffer circuit 3011 corresponding to the data strobe terminal DQSP are shown along with the output control signal to be input.

With respect to the output control signal, output control signals 324a, 324b, 324c, 324d, mode1, mode2 and mode3 are shown as the Y address-based control signal 324 in FIG. 5.

The output control signal 324a is input to the output buffer control circuit 3031 and the output buffer control circuit 307 for a data strobe signal. By setting output impedance of the output buffer circuit 3011 to be high impedance in the writing operation, data conflict between the output data and the input data input to the input buffer circuit 3021 is controlled.

The output buffer control circuit 3031 receives the data stored in the memory cell as the output control signal 324c via the data amplifier circuit 304, and transmits the data stored in the memory cell to the output buffer circuit 3011 by the output control signal 324b.

On the other hand, the output buffer control circuit 307 for a data strobe signal receives the output control signal 324d which is alternately repeated between 0 and 1 in its logic level, and transmits a signal which is alternately repeated between 0 and 1 in its logic level to the output buffer circuit 3011 by the output signal of the selector 352.

Further, the output control signal 324d is a signal generated in synchronization with the external clock signal CLK in the control logic circuit 311 in FIG. 5.

The delay line 351 is a circuit which receives the output control signal 324b to its input stage, of which the amount of delay is controlled by the output control signals mode1, mode2 and mode3, and which outputs a signal, which is input to the selector 352, from its output stage.

The delay line 351 may be configured to be delayed by the number of gate stages, or delayed by a time constant caused by resistive elements and capacitive elements, or latched by a signal which is made by shifting the phase of the input signal.

In addition, the delay line 351 may be configured to include a DLL (Delay Locked Loop) or a PLL (Phase Locked Loop).

Further, even though the above-mentioned control signal is described as the three signals mode1 to 3, it may be any numbers of signals.

The selector 352 is a circuit which selects the output signal or output control signal 324b of the above-mentioned delay line 351 in accordance with the logic level of the output signal of the OR circuit 353, and outputs a signal, which is input to the output buffer control circuit 307 for a data strobe signal, from its output stage.

Specifically, when the logic level of any one of the output control signals mode1 to mode3 is 1 in the test operation mode of a readout operation to be described later, the selector 352 delays the output control signal 324b by the amount of delay equivalent to the delay line 351, and outputs the data strobe signal for the output buffer control circuit 307.

On the other hand, in the typical operation mode of the readout operation, output control signal 324b is not delayed, but output to the data strobe signal for the output buffer control circuit 307.

Subsequently, the readout operation will be described.

In the readout operation, at the almost same time when the readout command (RED) is input to the command input terminal CMDP, the Y address signal is input to the address input terminal ADDP, and the data written in the memory cell of the Y address on the above-mentioned word line is read out from the memory cell array 401 to the data amplifier circuit 304.

The data read to the data amplifier circuit 304 is input to the output buffer control circuit 3031 as the output control signal 324c.

The output buffer control circuit 3031 transmits the data to the output buffer circuit 3011 by the output control signal 324b.

A transmit timing is adjusted by the output control signal 324b such that the data read from the data input and output terminal DQ0P, is synchronized with the external clock signal CLK which is delayed, for example, 2 clocks from the data readout command (RED).

The timing chart shown in FIG. 7 shows an example in which the continuous data D1 to D8 each having 8 bits are read out from the selected column address to the data input and output terminal DQ0P as the data input and output signal DQ0N in synchronization with the rising and falling of the external clock signal CLK.

In addition, regarding the data strobe signal DQS, since the output logic level of the OR circuit 353 is 0 in the typical operation mode of the readout operation, the timing at which the output buffer control circuit 307 for the data strobe signal transmits the data to the output buffer circuit 3011 occurs almost simultaneously with the output buffer control circuit 3031.

Therefore, as shown in the timing chart of FIG. 7, the data strobe signal DQSN outputs the data to the data strobe terminal DQSP at the almost same timing as the output of the above-mentioned data input and output signal DQ0N.

The output data of the data strobe signal DQS is alternatively changed to be the logical level 1 at the same time with the first bit of the data input and output and to be the logical level 0 at the same time with the second bit.

On the other hand, in the test operation mode of the readout operation, since the logical level of any one of the output control signal mode1 to mode3 in FIG. 6 becomes 1, the output logic level of the OR circuit 353 becomes 1.

Thus, the timing at which the output buffer control circuit 307 for the data strobe signal transmits the data to the output buffer circuit 3011 becomes a delayed time equivalent to the amount of delay which is determined by the delay line by the output buffer control circuit 3031.

Therefore, as shown in the timing chart of FIG. 7, the data strobe signal DQST outputs the data to the data strobe terminal DQSP at a timing slightly delayed from the data input and output signal DQ0T output.

Further, the data input and output signal DQ0T outputs the data to the data input and output terminal DQ0P at the almost same timing as the data input and output signal DQ0N in the above-mentioned typical operation mode.

Subsequently, a tester which tests the semiconductor device 300 including such a test operation mode will be described.

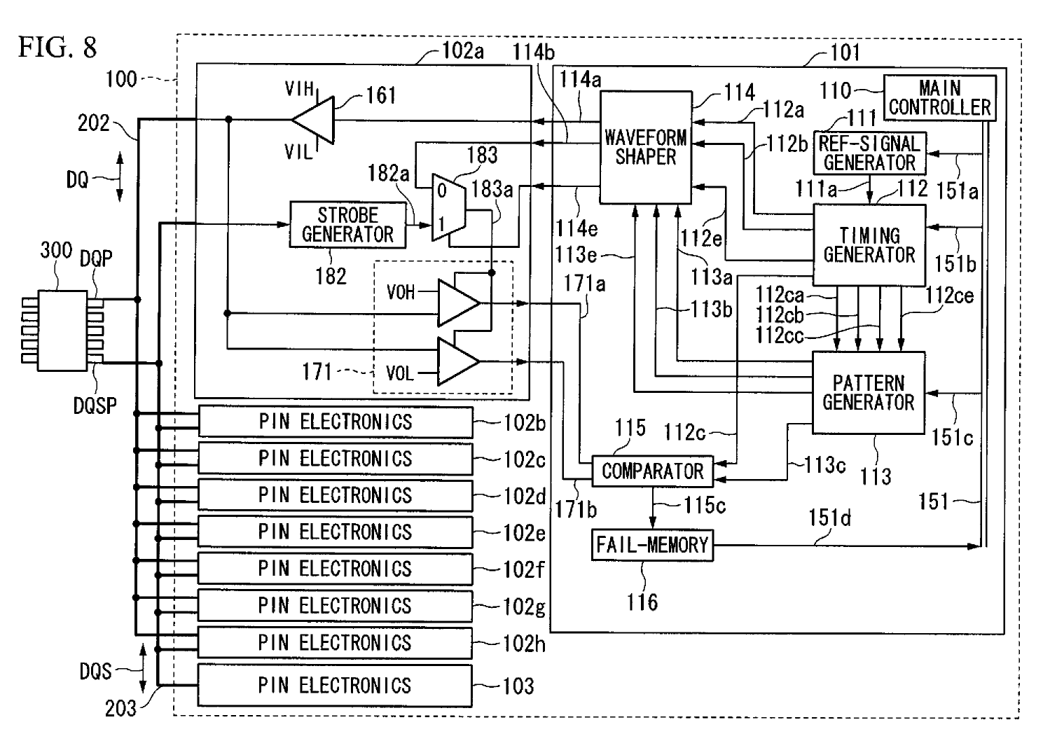

FIG. 8 is a diagram illustrating the configuration of the tester 100 which tests the above-mentioned semiconductor device 300.

FIG. 8 is different from FIG. 1 in that the delay line 181 connected to the strobe generating circuit 182 is not in the tester shown in FIG. 8.

In addition, since there is no delay line 181, the pin electronics 102a does not receive the delay control signal 114d. In addition, in the test signal control section 101 corresponding to the pin electronics 102a, the phase signal 112d, the phase signal 112cd and the pattern data signal 113d are not generated.

The transmission line 203, through which the data strobe signal DQS is transmitted, is connected to an input stage of the strobe generating circuit 182.

In the typical operation mode of the semiconductor device 300, the logic level of the selector control signal 114e to be input to the selector 183 of the tester 100 is set to 0, and in the test mode operation, the logic level is set to 1.

Setting of the logic level is set up in a program for testing the device prepared by a user. Meanwhile, the generation time of the strobe signal 114b in FIG. 8 is also set up by such a program.

Therefore, when the semiconductor device 300 is tested with the tester 100 of the embodiment, it is optimal to evaluate as follows by dividing the logic levels of the selector control signal 114e into 0 or 1.

When the logic level of the selector control signal 114e is 0, the strobe signal 183a in FIG. 1 becomes the strobe signal 114b output by the waveform shaper 114.

In such a case, as shown in FIG. 7, the strobe signal is generated after the elapse of a predetermined time (for example, after the elapse of tAC) from for example the second clock of the external clock signal CLK, and values in which the voltage levels of the data input and output signal DQ exist at VOH or higher or VOL or lower are compared by the comparator 171.

In addition, values in which the voltage levels of the data strobe signal DQS exist at VOH or higher or VOL or lower after the elapse of a predetermined time (for example, after the elapse of tDQSC) from the second clock of the external clock signal CLK are compared by the comparator 171.

That is, when the logic level of the selector control signal 114e is 0, it is evaluated whether the electrical characteristics tAC and tDQSC of the semiconductor device 300 are within a predetermined time.

On the other hand, when the logic level of the selector control signal 114e is 1, the amount of delay of the delay line 351 within a semiconductor device 300 is set up so that the strobe signal 182a is generated after the elapse of a predetermined time from the change point of the data strobe signal DQS, and values in which the voltage levels of the data input and output signal DQ exist at VOH or higher or VOL or lower are compared by the comparator 171.

In FIG. 7, the strobe signal STBT is the strobe signal 182a generated in the strobe generating circuit 182 in synchronization with rising and falling of the delayed data strobe signal DQST in the test mode of the semiconductor device 300.

That is, when the logic level of the selector control signal 114e is 1, the voltage level of the data input and output signal DQ is determined by using the timing of the data strobe signal DQS in consideration of the real usage state of the semiconductor device 300, it is evaluated whether data are changed like D1 to D8 and the expected value.

Meanwhile, it is possible to perform the evaluation with good accuracy by setting up the amount of delay of the delay line 351 selected in response to the output control signals mode1, mode2, and mode3 in FIG. 6 described above to a value supposed from the real practice of the semiconductor device in design.

As described above, the semiconductor device according to the embodiment is a semiconductor device (semiconductor device 300) in which a reference clock (data strobe signal DQS) provided for reception and transmission of data along with data to be output (data input and output signal DQ) is output, and is a semiconductor device characterized in that the reference clock (data strobe signal DQS) is delayed and output in a test mode operation.

Further, the tester of the embodiment is a testing apparatus (tester 100) for testing the above-mentioned device (device 300), and is a tester (tester 100) characterized in that a reference clock (data strobe signal DQS) provided for reception and transmission of data along with data (data input and output signal DQ) to be output is output from the device (device 100), and that detection of the data (data input and output signal DQ) is performed in response to a strobe pulse (strobe signal 182a) generated in synchronization with a timing of the rising and falling of the reference clock (data strobe signal DQS).

With the tester according to the embodiment of the invention, since the delay line that delays the reference clock exists in the device as described above, variations in the data input and output signal DQ varied with the lapse of time (thermal variation) of the semiconductor device, or so-called jitters reach the delay line in the same condition.

Therefore, with the tester according to the embodiment of the invention, an effect is exhibited that it is possible to perform the detection of variations in data with a higher degree of accuracy.

The term “configured” is used to describe a component, section or part of a device includes hardware and/or software that is constructed and/or programmed to carry out the desired function.

It is apparent that the present invention is not limited to the above embodiments, but may be modified and changed without departing from the scope and spirit of the invention.

What is claimed is:

1. An apparatus testing a semiconductor device, the apparatus comprising:
a first strobe signal generating circuit that generates a first strobe signal in response to a reference clock supplied from the semiconductor device; and
a detecting circuit that detects a data signal, supplied from the semiconductor device, based on the first strobe signal.

2. The apparatus according to claim 1, wherein the reference clock is supplied from the semiconductor device to be accompanied with the data signal.

3. The apparatus according to claim 2, wherein the reference clock is a data strobe signal generated by the semiconductor device.

4. The apparatus according to claim 1, further comprising:
a delay circuit that receives the reference clock from the semiconductor device, the delay circuit delaying the reference clock to generate a delayed reference clock,
wherein the first strobe signal generating circuit receives the delayed reference clock from the delay circuit, the first strobe signal generating circuit generates the strobe signal in response to the delayed reference clock.

5. The apparatus according to claim 4, further comprising:
a delay control signal generating circuit that generates a delay control signal, the delay control signal generating circuit supplying the delay control signal to the delay circuit,
wherein the delay circuit delays the reference clock based on the delay control signal.

6. The apparatus according to claim 1, further comprising:
a second strobe signal generating circuit that generates a second strobe signal at a predetermined tinning; and
a selector that selects one of the first and second strobe signals,
wherein the detecting circuit receives a selected one of the first and second strobe signals from the selector, and the detecting circuit detects the data signal using the selected one of the first and second strobe signals.

7. The apparatus according to claim 6, further comprising:
a selector control signal generating circuit that generates a selector control signal, the selector control signal generating circuit supplying the selector control signal to the selector,
wherein the selector selects one of the first and second strobe signals based on the selector control signal.

8. The apparatus according to claim 1, wherein the apparatus comprises a plurality of pin electronics connected to the semiconductor device, each of the plurality of pin electronics receiving the data signal and the reference clock, and each of the plurality of pin electronics comprising the first strobe signal generating circuit and the detecting circuit.

9. The apparatus according to claim 4, wherein the apparatus comprises a plurality of pin electronics connected to the semiconductor device, each of the plurality of pin electronics receiving the data signal and the reference clock, and each of the plurality of pin electronics comprising the first strobe signal generating circuit, the detecting circuit and the delay circuit.

10. The apparatus according to claim 4, wherein the apparatus comprises a plurality of pin electronics connected to the semiconductor device, and a test signal control unit connected to the plurality of pin electronics, each of the plurality of pin electronics receiving the data signal and the reference clock, and each of the plurality of pin electronics comprising the first strobe signal generating circuit, and the detecting circuit, the test signal control unit comprises the delay circuit.

11. The apparatus according to claim 6, wherein the apparatus comprises a plurality of pin electronics connected to the semiconductor device, and a test signal control unit connected to the plurality of pin electronics, each of the plurality of pin electronics receiving the data signal and the reference clock, and each of the plurality of pin electronics comprising the first strobe signal generating circuit, the detecting circuit and the selector, the test signal control unit comprises the second strobe signal generating circuit.

12. The apparatus according to claim 1, wherein the semiconductor device comprises:
a data output unit that outputs the data signal; and
a delayed reference clock output unit that outputs a delayed reference clock, the data signal being output based on the delayed reference clock, and
wherein the semiconductor device supplies the data signal to the apparatus and supplies the delayed reference clock to the apparatus as the reference clock.

13. A method of testing a semiconductor device, the method comprising:
supplying a reference clock and a data signal from the semiconductor device to an apparatus;
generating a first strobe signal in response to the reference clock; and
detecting the data signal based on the first strobe signal.

14. The method according to claim 13, further comprising:
delaying the reference clock to generate a delayed reference clock,
wherein generating the strobe signal comprises generating the strobe signal in response to the delayed reference clock.

15. The method according to claim 13, further comprising:
generating a second strobe signal at a predetermined timing; and
selecting one of the first and second strobe signals,
wherein detecting the data signal comprises detecting the data signal using the selected one of the first and second strobe signals.

16. The method according to claim 13, wherein generating the first strobe signal and detecting the data signal are performed by each of a plurality of pin electronics included in an apparatus testing the semiconductor device.

17. The method according to claim 14, wherein delaying the reference clock is performed in an apparatus testing the semiconductor device.

18. The method according to claim 14, wherein delaying the reference clock is performed in the semiconductor device.

19. An apparatus comprising:
a first pin receiving a reference clock signal;
a second pin receiving a data signal;
a first strobe signal generating circuit electrically coupled to the first pin and generating a first strobe signal in response to the reference clock signal;
a second strobe signal generating circuit generating a second clock signal, the second clock signal being free from the reference clock signal;
a selector receiving the first and second strobe signal and outputting one of the first and second strobe signal;
a reference voltage generating circuit generating a reference voltage; and
a detection circuit electrically coupled to the second pin to receive the data signal, receiving the one of the first and second strobe signal and the reference voltage, and comparing a first logic level of the data signal with a second logic level of the reference voltage at a timing based on the one of the first and second strobe signal.

20. The apparatus according to claim 19, further comprising:
a delay circuit connected between the first pin and the first strobe signal generating circuit so as to delay the reference clock signal supplied from the first pin, the delay circuit generating a delayed reference clock signal, and
wherein the first strobe signal generating circuit generates the first strobe signal in response to the delayed reference clock signal.
